(19) United States
(12) Patent Application Publication
(10) Pub. No.: US 2021/0355580 A1
(43) Pub. Date: Nov. 18, 2021

(54) Systems and Methods for Depositing a Layer on a Substrate Using Atomic Oxygen

(71) Applicant: Tokyo Electron Limited, Tokyo (JP)

(72) Inventor: Anthony Dip, Austin, TX (US)

(21) Appl. No.: 15/930,737

(22) Filed: May 13, 2020

(51) Int. Cl. C23C 16/455

(52) U.S. Cl. CPC C23C 16/45534; C23C 16/45544; C23C 16/45553; C23C 16/45565

(57) ABSTRACT

A layer is deposited on a substrate using atomic oxygen in an atomic layer deposition (ALD) process. The gases used to generate atomic oxygen are mixed and heated within a gas activation chamber. In one embodiment, the gas activation chamber is positioned beneath a showerhead of a spatial ALD system for receiving one or more gases injected from the showerhead. The gases are mixed within the gas activation chamber and passed over a hot surface to produce reaction byproducts, including atomic oxygen. The hot surface heats the gas mixture to a high temperature (e.g., above 550 C) sufficient to produce meaningful concentrations of atomic oxygen. The gas activation chamber then transports the heated gas mixture containing the atomic oxygen to the substrate surface at an elevated temperature to minimize recombination of the atomic oxygen, the high temperature of the gas activation chamber being higher than the temperature of the substrate.

### BACKGROUND

The present disclosure relates to the processing of substrates. In particular, it provides an apparatus and method for treating surfaces of substrates.

Atomic layer deposition (ALD) is a known technique for forming layers on a substrate. In atomic layer deposition, substrates are cyclically exposed to alternate gaseous species (or precursors). The gaseous species react with the substrate surface in a self-limiting or near self-limiting manner. A thin film may be slowly formed by repeating the cycles of alternating gaseous species.

A variety of process tools may be utilized in atomic layer deposition processes. For example, batch furnace type systems may be utilized. Single substrate systems in which a process chamber is filled with gas and evacuated for a single substrate may also be utilized. Yet another system is a spatial ALD system. In spatial ALD systems, substrates travel at relatively high speeds past a plurality of gas sources (e.g., gas injectors, a gas showerhead, or a gas showerhead with injector outlets), which inject the necessary gases proximate the substrate surface to accomplish the ALD process steps as the substrate rotates in a cyclical manner.

One known atomic layer deposition process is the formation of atomic layer deposition oxide films, such as for example, silicon oxide. An exemplary ALD process for forming silicon oxide may include sequentially exposing the substrate surface to a silicon containing precursor gas followed by exposure of the substrate surface to atomic oxygen (O). Atomic oxygen is often a preferred oxidizer due to excellent oxidation properties that result in a high quality silicon oxide deposited film.

For example, the substrate may first be exposed to a silicon containing precursor gas, such as dichlorosilane (DCS), trichlorosilane, etc. Next, the substrate may be exposed to atomic oxygen. To produce atomic oxygen, a combination of oxygen (O₂) and hydrogen (H₂) may be injected above the substrate surface at relatively high temperatures (e.g., 550 C to 1000 C). When injected at temperatures above 550 C, the O₂ and H₂ mix and react to form gas phase byproducts including atomic oxygen (O). The atomic oxygen produced at the substrate surface reacts with the silicon on the substrate to form silicon oxide. The process typically occurs while the substrate is heated and the O₂ and H₂ are injected at desired ratios and a low pressure (e.g., sub 10 Torr). Such techniques are known as low pressure radical oxidation (LPRO).

It is noted that the gas chemistries described above are merely exemplary known chemistries for atomic layer deposition of an oxide, and it is recognized that other chemistries (e.g., O₃ or H₂O) may be used for atomic layer deposition of an oxide and/or other dielectric materials.

One exemplary system for achieving the atomic layer deposition process described above is shown in FIG. 1. The system shown in FIG. 1 is a spatial ALD system or tool. The creation of atomic oxygen in systems, like spatial systems, may have other uses in addition to atomic layer deposition processes. For example, other uses of atomic oxygen surface treatments are known. In one embodiment, atomic oxygen may be provided at a surface so as to diffuse into the surface to form a diffused silicon oxide layer.

FIG. 1 provides a top-down view of a substrate process tool 100 (i.e., a spatial ALD system) as seen inside a process chamber 105 of the substrate process tool 100. As shown in FIG. 1, a platen 110 is provided within the process chamber 105 for holding one or more substrates 115. Each of the substrates 115 may be arranged on a susceptor (not shown), which provides heat to the substrate. A number of showerheads and purge sources may also be provided within the process chamber 105, and may be located above the platen 110 for providing various gases to the substrate.

In the spatial ALD system shown in FIG. 1, a showerhead 120 is located above the platen 110 for providing an oxidizer (such as, for example, atomic oxygen) to the one or more substrates 115. In one embodiment, the showerhead 120 may be a low pressure radical oxidation (LPRO) showerhead. A precursor showerhead 125 is also located above the platen 110 for providing a precursor gas to the one or more substrates 115. As the platen 110 rotates (as indicated by the arrows), the one or more of substrates 115 are moved in sequence under the precursor showerhead 125 and then under the showerhead 120 to perform one cycle of the atomic layer deposition process. The rotation of the platen 110 and the substrates 115 may be repeated for a number of ALD cycles. Gas outlet pumping ports 130 may also be provided, as shown in FIG. 1.

The substrate process tool 100 may also include a number of purge sources 128. Purge sources 128 provide a gas purge (e.g., a nitrogen purge or other inert gas purge) after the one or more substrates 115 rotate past each showerhead (i.e., the showerhead 120 and the silicon precursor showerhead 125) to prevent the oxidizer and the precursor gases from mixing. The purge sources 128 may be configured in any number of manners, such as a line of gas injectors, a line of gas injectors in a separate partitioned zone, a showerhead, etc. Although not shown in FIG. 1, a controller may be provided for controlling various operating parameters of the spatial ALD system including, for example, temperatures, gas flows, pressures, rotation speeds, number of ALD cycles, etc.

FIG. 2 provides a cross sectional view of the platen 110 and the showerhead 120 shown in FIG. 1 when a substrate 115 is rotated under the showerhead 120. As shown in FIG. 2, the showerhead 120 injects gases (as indicated by arrows 205) into a process space 210 above the substrate 115. The gases injected into the process space 210 from the showerhead 120 are utilized as part of the atomic deposition process, and in some cases, may include an oxidizer such as atomic oxygen. A more detailed cross sectional view of the platen 110, LPRO showerhead 120, and substrate 115 is provided in FIG. 3. As shown in FIG. 3, the LPRO showerhead 120 may include a plurality of injector holes 305 for injecting the gases (as shown by arrows 205) into the process space 210, and a skirt 310 surrounding the injector holes 305 for containing the gases within the process space 210. A perspective view of the LPRO showerhead 120, the skirt 310 and the injector holes 305 is shown in FIG. 4.

Atomic oxygen is an oxidizer known to provide excellent film properties for the oxidation of silicon to form silicon oxide and other dielectric films on a substrate. However, relatively high temperatures (e.g., 550 C to 1000 C) are needed to form atomic oxygen. As noted above, one method for producing atomic oxygen (O) is to inject a combination of H₂/O₂ above the substrate surface at temperatures above 550 C (e.g., 700-800 C), which results in atomic oxygen formation at the substrate due to the high injection temperature. However, many metal oxide dielectric thin films (such as, e.g., aluminum oxide (AL₂O₃), hafnium oxide (HfO₂), zirconium oxide (ZrO₂), etc. used for dynamic random access storage nodes) must be deposited at lower substrate temperatures (e.g., 500 C or below) to avoid undesirable phase changes and/or poor deposition characteristics. Since meaningful quantities of atomic oxygen cannot be obtained at such low substrate temperatures, other oxidizers (e.g., O₂, O₃ or H₂O) are often used in such deposition processes in lieu of atomic oxygen.

Thus, it would be desirable to provide a system and method that produces atomic oxygen without requiring high substrate temperatures (e.g., above 550 C).

### SUMMARY

Systems and methods are provided herein for depositing a layer on a substrate using atomic oxygen as an oxidizer. In the systems and methods disclosed herein, the gases used to generate atomic oxygen are mixed and heated prior to injection into a process space arranged above a substrate. In the disclosed embodiments, gas mixing occurs within a gas activation chamber arranged between a showerhead (e.g., a LPRO showerhead) of an atomic layer deposition (ALD) system and a substrate being processed by the ALD system.

In some embodiments, the gas activation chamber may be positioned beneath the showerhead, so that the gas activation chamber receives one or more gases injected from the showerhead. The gases received from the showerhead are mixed within the gas activation chamber and passed over a hot surface to produce reaction byproducts, including but not limited to, atomic oxygen. The hot surface heats the gas mixture to a high temperature (e.g., a temperature above 550 C) sufficient to produce meaningful concentrations (e.g., up to 5%) of atomic oxygen. The gas activation chamber then transports the heated gas mixture containing the atomic oxygen to the substrate surface, while maintaining as high a gas temperature as possible, to minimize recombination of the atomic oxygen.

In a system embodiment, a system for atomic layer deposition (ALD) processing of a substrate is provided, the system comprising: a gas source configured to provide one or more gases, a gas activation chamber arranged between the gas source and the substrate, and a heat source. The gas activation chamber is coupled to receive the one or more gases provided from the gas source, wherein the gas activation chamber is configured so that the one or more gases are mixed within the gas activation chamber and heated at a first temperature to produce a reaction byproduct which includes atomic oxygen. In addition, the gas activation chamber is configured to transport a heated gas mixture containing the reaction byproduct to the substrate at an elevated temperature. Further, the system is configured to allow the substrate to be maintained at a second temperature, the second temperature being lower than the first temperature.

Various embodiments of the system are provided. In one embodiment, the first temperature is between 500 C and 1200 C and the second temperature is lower than 500 C. In another embodiment, the gas source comprises a showerhead, the showerhead is configured to inject the one or more gases into the gas activation chamber. In another embodiment, the gas activation chamber includes a plurality of injector holes. In still another embodiment, a gas activation chamber injection hole pattern matches a showerhead injector hole pattern. According to another embodiment, the gas activation chamber is formed from a material having low thermal conductivity. In another embodiment, the gas activation chamber is formed from quartz. In still another embodiment, the gas activation chamber includes the heat source, one or more heating elements of the heat source heating the one or more gases within the gas activation chamber, and gas activation chamber maintaining the heated gas mixture containing the reaction byproduct at the elevated temperature while transporting the heated gas mixture containing the reaction byproduct to the substrate. In another embodiment, a baffle plate containing a plurality of exhaust holes is provided on an underside of the gas activation chamber to deliver the heated gas mixture containing the reaction byproduct to the substrate. In one embodiment, the baffle plate comprises a plurality of thin plates having complementary hole patterns, which block direct line of sight from the one or more heating elements to the substrate. In another embodiment, the system is a spatial atomic layer deposition (ALD) system having a rotating platen. In still another embodiment, the system is configured to perform a low pressure radical oxidation (LP RO) process by exposing the substrate to a precursor before the substrate is exposed to atomic oxygen, and wherein the atomic oxygen is generated within the gas activation chamber and transported to the substrate, where it reacts with the precursor to deposit a layer on the substrate. In another embodiment, the first temperature is above 550 C and the second temperature is below 500 C.

In a method embodiment, a method for performing atomic layer deposition of a layer on a substrate. The method may comprise exposing the substrate to a precursor; providing one or more gases to a gas activation chamber arranged above the substrate after the substrate is exposed to the precursor, mixing the one or more gases within the gas activation chamber at a first temperature to generate a reaction byproduct, and transporting a heated gas mixture containing the reaction byproduct to the substrate, wherein the reaction byproduct reacts with the precursor to form the layer on the substrate, the substrate being at a second temperature, the first temperature higher than the second temperature.

Various embodiments of the method are provided. In one embodiment, the reaction byproduct generated within the gas activation chamber comprises atomic oxygen and the layer deposited on the substrate comprises an oxide. In another embodiment, the precursor contains a metal and the layer deposited on the substrate is a metal oxide. In another embodiment, the one or more gases comprise oxygen (02) and hydrogen (H2). In still another embodiment, the one or more gases include ozone (O3). In yet another embodiment of the method, the first temperature is above 550 C and the second temperature is below 500 C. In another embodiment, the method is a spatial atomic layer deposition (ALD) process using a rotating platen, wherein the method further comprises cyclically exposing the substrate to the precursor and the reaction byproduct.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 illustrates a conventional spatial atomic layer deposition (ALD) system.

FIGS. 2-4 illustrate examples of showerheads that may be used with the spatial ALD system of FIG. 1.

FIG. 5 is a simplified block diagram of a gas activation chamber in accordance with the techniques disclosed herein.

FIG. 6 is a cross-sectional view through the gas activation chamber of FIG. 5.

FIG. 7A is a top view of the gas activation chamber of FIG. 6 through the section line 7A-7A of FIG. 6.

FIG. 7B is a cross-sectional view through the gas activation chamber of FIG. 6 through the section line 7B-7B of FIG. 6.

FIG. 7C is a bottom perspective view of the gas activation chamber of FIG. 6.

FIG. 8 illustrates a side perspective view of an exemplary gas activation chamber that may be included within a spatial ALD system.

FIG. 9 is a flowchart diagram illustrating an exemplary method utilizing the techniques disclosed herein.

### DETAILED DESCRIPTION

Systems and methods are provided herein for depositing a layer on a substrate. Prior to performing the techniques described herein, the substrate may be exposed to a precursor gas. In one embodiment, the precursor gas may be a metal containing gas, such as TMA (trimethylaluminium); AlCl₃ (Aluminum trichloride); Zr(N(CH3)₂)₄ (tetrakis (dimethylamido) zirconium); Zr(N(CH₃)(C₂H₅))₄ (Tetrakis (ethylmethylamido) zirconium); Hf(N(CH₃)(C₂H₅))₄ (tetrakis (ethylmethylamido) hafnium); etc.) used to form metal oxides such as for example aluminum oxide (AL203), hafnium oxide (HfO2), zirconium oxide (ZrO2), etc. In one embodiment, the precursor gas may be a silicon containing gas, such as, but not limited to, dichlorosilane (DCS), trichlorosilane, etc. Once exposed to the precursor gas, the substrate may be exposed to an oxidizer, which reacts with the precursor on the substrate to deposit an oxide layer on the substrate. In the disclosed embodiments, atomic oxygen is generated within the system and used as the oxidizer. The deposited layer may be a silicon oxide or a metal-oxide or any other layer for which it may be desirable to utilize atomic oxygen, depending on the precursor gas supplied to the substrate.

In the systems and methods disclosed herein, the gases used to generate atomic oxygen are mixed and heated prior to injection into a process space arranged above a substrate. In the embodiments disclosed herein, gas mixing occurs within a gas activation chamber arranged between a gas source (e.g., gas injectors, a gas showerhead, or a gas showerhead with injector outlets) of an atomic layer deposition (ALD) system and a substrate being processed by the ALD system. In some embodiments, the gas activation chamber is positioned beneath a showerhead of a spatial ALD system, so that the gas activation chamber receives one or more gases injected from the showerhead. In one embodiment, the gas activation chamber may be arranged below a low pressure radical oxidation (LPRO) showerhead, such as the LPRO showerhead 120 shown in FIG. 1 and described above. The gases received from the showerhead are mixed within the gas activation chamber and passed over a hot surface to produce reaction byproducts, including but not limited to, atomic oxygen. The hot surface heats the gas mixture to a high temperature (e.g., a temperature above 550 C) sufficient to produce meaningful concentrations (e.g., up to 5%) of atomic oxygen. The gas activation chamber then transports the heated gas mixture containing the atomic oxygen to the substrate surface, while maintaining as high a gas temperature as possible, to minimize recombination of the atomic oxygen.

Mixing the gases within the gas activation chamber, as opposed to mixing the gases at the substrate surface, enables meaningful concentrations (e.g., up to 5%) of atomic oxygen to be produced away from the substrate at high temperatures (e.g., temperatures above 550 C). The gas activation chamber preserves the initial concentration of atomic oxygen by transporting the heated gas mixture to the substrate at an elevated temperature. By generating atomic oxygen at high temperatures away from the substrate, and transporting the heated gas mixture containing the atomic oxygen to the substrate, the techniques described herein enable formation of thin films that must be deposited at low temperatures (e.g., temperatures below 500 C), such as, e.g., AL₂O₃, HfO₂, ZrO₂, etc. Further, the techniques described may be utilized in situations where a film may be deposited at higher temperatures (for example silicon oxide films) but for which it may be desirable due to the particular process step to maintain the substrate at a lower temperature.

FIG. 5 is a simplified block diagram illustrating one embodiment of a gas activation chamber 400 in accordance with the techniques described herein. Although not strictly limited to such, the gas activation chamber 400 may be incorporated within a spatial ALD system having a rotating platen 110, as shown in FIG. 1. In some embodiments, the gas activation chamber 400 may be arranged between a showerhead of a spatial ALD system and a substrate 115 provided on a rotating platen 110. Although not shown in the figures, the substrate 115 may be arranged on a susceptor provided on the rotating platen 110. As known in the art, a susceptor may be used to heat the substrate to a desired substrate temperature during one or more steps of an atomic layer deposition process.

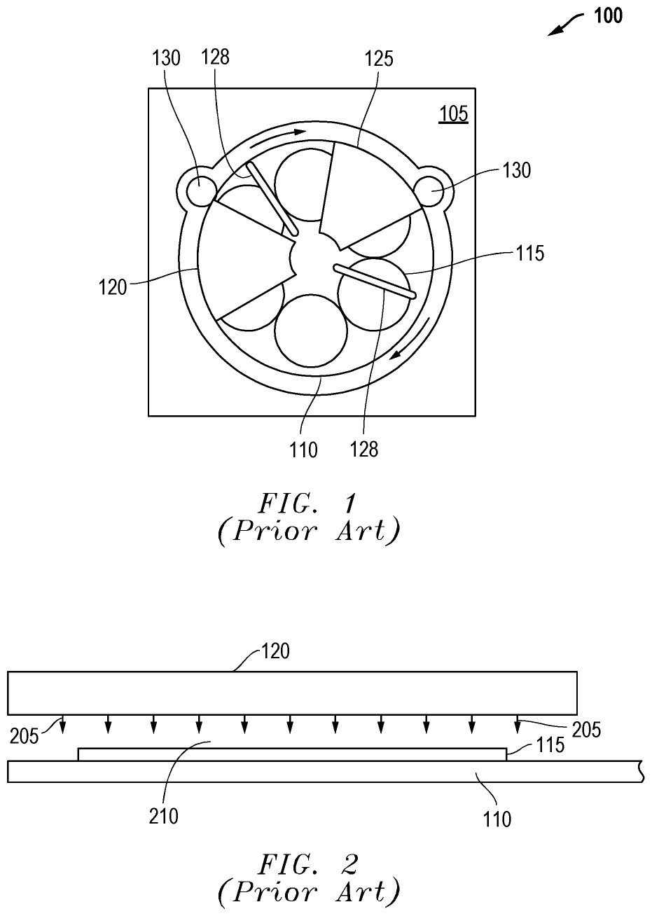

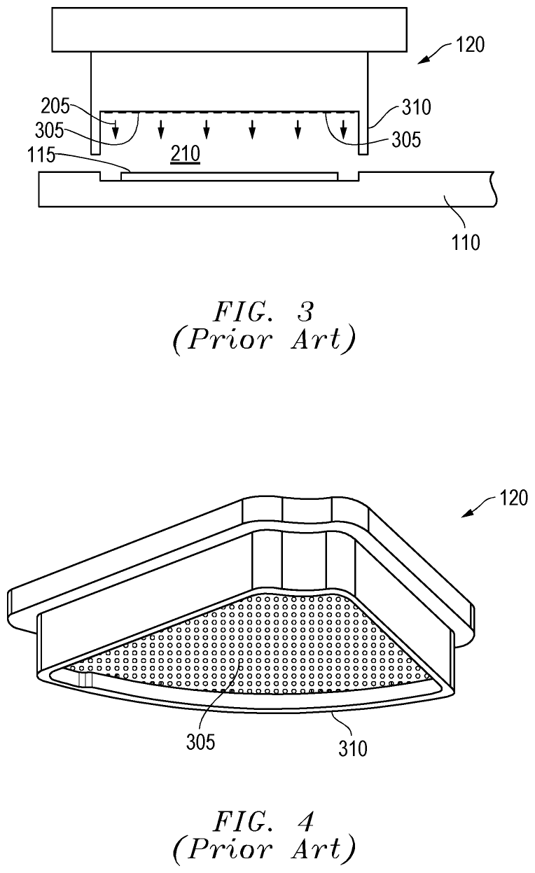

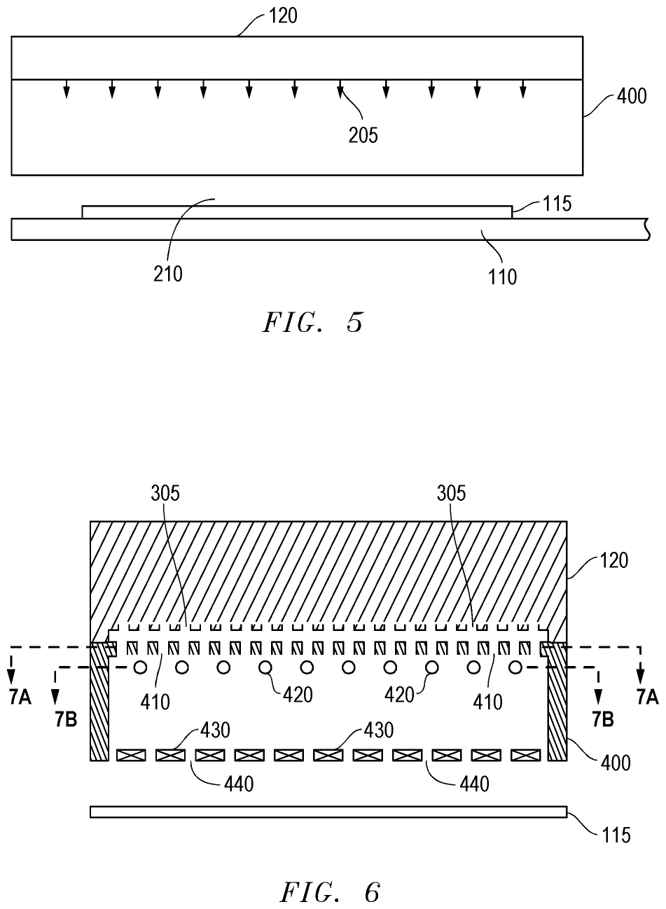

The gas activation chamber 400 may be coupled to receive one or more gases from a showerhead of a spatial ALD system, as shown for example in FIG. 5. In some embodiments, the LPRO showerhead 120 shown in FIGS. 1-4 may be used in the embodiment shown in FIG. 5 to inject one or more gases evenly throughout an upper portion of the gas activation chamber 400. As noted above and shown in FIGS. 3 and 4, the showerhead 120 may include a plurality of injector holes 305 for injecting the gases (as shown by arrows 205) into the gas activation chamber 400, and/or a skirt 310 surrounding the injector holes for containing the gases. To enable the injected gases to pass into the gas activation chamber 400, the injector holes 305 in the LPRO showerhead 120 may be aligned with injection holes 410 provided in an upper surface of the gas activation chamber 400, as shown in FIG. 6 and described in more detail below. In some embodiments, such alignment, though is not required.

In some embodiments, the gas activation chamber 400 may be directly connected to, or incorporated with, an underside of the showerhead for receiving the gases injected from the showerhead. In other embodiments, the gas activation chamber 400 may be inserted below and spaced apart from the underside of the showerhead. Regardless of spacing, the gases received from the showerhead are mixed within the gas activation chamber 400 and heated at sufficiently high temperatures (e.g., temperatures above 550 C) to produce reaction byproducts, such as atomic oxygen. In one embodiment, a temperature range of 500 C to 1200 C may be utilized for generating reaction byproducts such as atomic oxygen. Once mixed, the gas activation chamber 400 transports the heated gas mixture containing the atomic oxygen to the process space 210 above the substrate 115 at an elevated temperature. To a large extent, the temperature of the baffle plate determines the gas temperature as it exits the activation chamber. If the substrate is biased at 450 C and the heaters are set to 1000 C, for example, the baffle plate will be about 550 C and the gas within the activation chamber will cool from about 1000 C to about 550 C. However, the cooling rate is not linear and mist of the cooling occurs at or near the baffle plate. The temperature of the baffle plate may be determined by radiative heating from the activation chamber coils, so depending on the design this will vary. Without the baffle plate, the gas will cool more quickly In this manner, a higher temperature may be achieved in the gas activation chamber but the deposition at the substrate occurs at a lower temperature. Thus, the film deposition may occur at a lower temperature which may be suitable for some films, for example metal-oxide dielectric thin films.

In one embodiment, the showerhead may provide a desired ratio of oxygen (O₂) and hydrogen (H₂) to the gas activation chamber 400 at a relatively low pressure (e.g., below 10 Torr). When O₂ and H₂ are mixed at low pressure and high temperature (e.g., greater than 550 C and more particularly greater than 700 C and even around 1100 C), the O₂/H₂ reaction proceeds slowly, and while H₂O is produced (about 20-30%), up to about 5% (at 1100 C) and up to about 1% (at 700 C) of atomic oxygen (O) may be also produced as a reaction byproduct.

In another embodiment, the showerhead may provide oxygen (O₂) and ozone (O₃) to the gas activation chamber 400 at a relatively low pressure (e.g., below 10 Torr). When up to 15% of O₃ is mixed with O₂ at low pressure and temperatures between 400 C to 1200 C, about 1-2% of atomic oxygen (O) may be produced from the decomposition of O₃. Generally, higher temperatures slow the recombination of atomic oxygen to form O₂. 500 C may be enough, but the lifetime of the atomic oxygen may be short lived. 1000 C or hotter may thus be desired. Note, typically it is desired to have most atomic oxygen but there are cases where less may be desirable. Specifically, low concentrations of atomic oxygen in the first monolayer or two for certain films may be desired as using high concentrations of atomic oxygen may damage the underling base film before enough of the new film is deposited. In these cases, low concentrations of atomic oxygen could be first used to establish a few monolayers to act as a barrier film then the atomic oxygen concentration is increased to achieve the best effect on film quality. A desirable quality with the gas activation chamber described herein is adjustability via the gas chemistry and heating temperature.]

FIG. 6 provides a cross-sectional view through the showerhead 120 and the gas activation chamber 400 shown in FIG. 5. In some embodiments, the showerhead 120 may be formed from a wide variety of thermally conductive materials. In one embodiment, aluminum may be used to form the showerhead 120 due to its easy machining and high thermal conductivity. Since aluminum cannot withstand high temperatures, conventional cooling methods, such as interior channels for liquid coolant, may be incorporated within the showerhead 120 when aluminum is used. Although aluminum is provided as an example, other materials may be used to fabricate the showerhead 120 in other embodiments.

It is noted that, although the gas activation chamber 400 is shown in FIGS. 5 and 6 as being coupled for receiving one or more gases from an LPRO showerhead 120 of a spatial ALD system, the gas activation chamber 400 is not so strictly limited, and may instead be coupled for receiving gases from other gas sources and/or other systems. In one alternative embodiment, the showerhead 120 shown in FIGS. 1-5 may be replaced with a gas injection manifold, gas injectors or another gas source. As mentioned, though the coupling in the figures of the gas activation chamber and the showerhead is a direct connection, the two elements may alternatively be spaced apart from each other.

In one embodiment, the gas activation chamber 400 is an insulated chamber (for example a quartz chamber), which is used to heat the gas mixture and maintain the reactant gases (i.e., the heated gas mixture) at an elevated temperature until they are provided to the substrate 115. In some embodiments, a plurality of injection holes 410 may be formed within an upper surface of the gas activation chamber 400 to enable the gases injected from injector holes 305 of the showerhead 120 to pass into the gas activation chamber 400. In one embodiment, the gas activation chamber injection hole pattern formed by injection holes 410 may match the showerhead injector hole pattern formed by the injector holes 305.

In some embodiments, one or more heaters or heating elements 420 may be provided within the gas activation chamber 400, as shown in FIG. 6, to operate as heat sources for heating the gases within the gas activation chamber 400 and for maintaining the heated gas mixture at an elevated temperature. The materials used to form the heating elements 420 may be capable of high thermal operation (e.g., about 1000 C-1200 C) and have high purity or excellent chemical stability. In one embodiment, carbon wire heaters comprised of quartz tubes having an internal carbon filament may be used for the heating elements 420. Although carbon wire heaters are provided herein as an example, other types of heating elements 420 that meet the above mentioned requirements may also be used.

The gas activation chamber 400 may be formed from a wide variety of thermally insulative materials. In one embodiment, quartz may be used to form the gas activation chamber 400 due to its low thermal conductivity. In one preferred embodiment, an opaque quartz may be used to form the gas activation chamber 400. In addition to providing low thermal conductivity, opaque quartz provides an excellent barrier to infrared (IR) radiation by blocking over 95% of the IR radiation at the desired thermal operating point (e.g., about 1000 C-1200 C) of the heating elements 420. Conversely, clear quartz is only effective at absorbing about 10-15% of the IR radiation in the desired temperature range. Therefore, opaque quartz may be used to form the gas activation chamber 400, in at least one preferred embodiment, to contain IR radiation within the gas activation chamber and to prevent excessive heat transfer from the heating elements 420 to the substrate 115.

As shown in FIG. 6, a baffle plate 430 containing a pattern of exhaust holes 440 may be provided on the underside of the gas activation chamber 400 to deliver the heated gas mixture containing the atomic oxygen to the substrate. The baffle plate 430 may be directly connected to, or incorporated with, the gas activation chamber 400. In one embodiment, the baffle plate 430 may be formed from opaque quartz. In some embodiments, the baffle plate 430 may comprise several thin plates having complementary hole patterns. Such hole patterns may be in thin spaced apart plates in in which the hole patterns are complementary but offset, for example, to block direct line of sight from the heating elements 420 to the substrate 115.

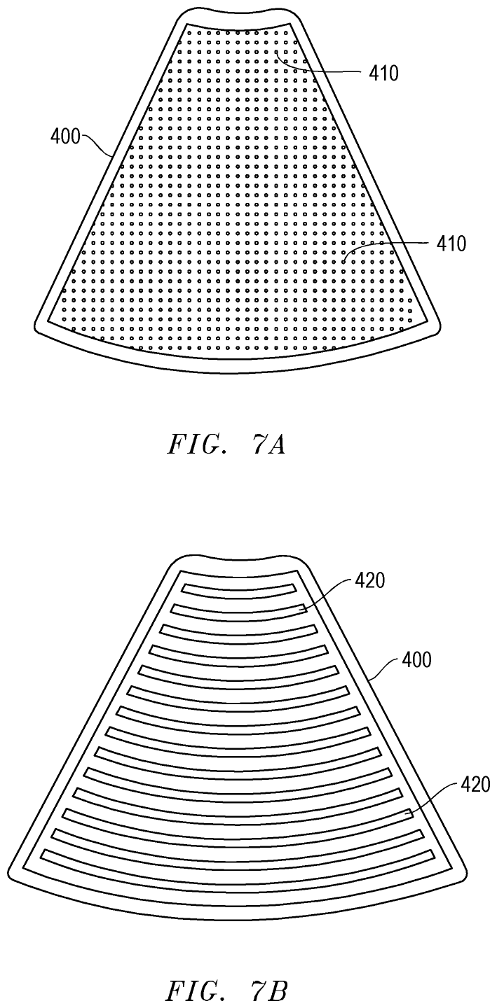

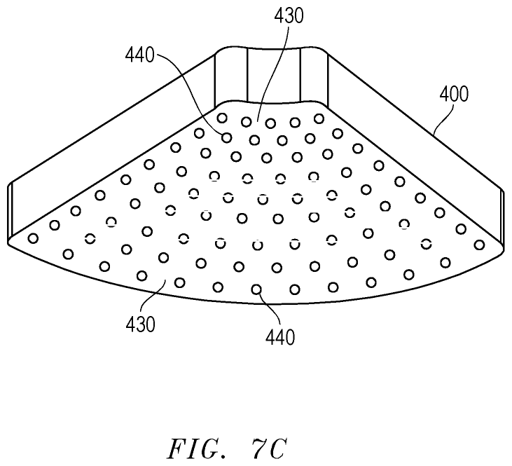

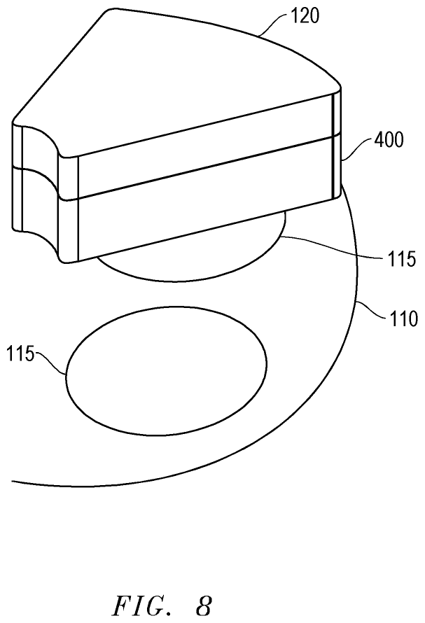

Additional views of an exemplary gas activation chamber 400 are provided in FIGS. 7A, 7B, 7C and 8. More specifically, FIG. 7A illustrates a top view of the gas activation chamber 400, as seen along section line 7A-7A of FIG. 6. FIG. 7B illustrates a cross-sectional view of the gas activation chamber 400 as seen along section line 7B-7B of FIG. 6. FIG. 7C illustrates a bottom perspective view of the gas activation chamber 400. FIG. 8 provides an example working model of a gas activation chamber 400 that may be used within an ALD system to generate atomic oxygen. In the embodiment shown in FIG. 8, the gas activation chamber 400 is provided within a spatial ALD system and inserted between a showerhead 120 and a rotating platen 110 of the spatial ALD system. Compared to conventional spatial ALD systems, which position the showerhead directly above the rotating platen without intervening structure, the showerhead 120 shown in FIG. 8 has the gas activation chamber 400 inserted below the showerhead 120 and above the substrate 115 provided on the rotating platen 110.

The gas activation chamber 400 shown in FIGS. 7A, 7B, 7C and 8 may generally include all of the components shown in FIGS. 5 and 6 and discussed above. Specifically, the gas activation chamber 400 shown in FIGS. 7A, 7B, 7C and 8 may include a plurality of injection holes 410, one or more heating elements 420 and a baffle plate 430 containing a pattern of exhaust holes 440. As noted above, one or more gases injected from the showerhead 120 may be mixed and heated within the gas activation chamber 400 to produce reaction byproducts before the heated gas mixture is delivered to the substrate 115 provided on the rotating platen 110. It will be recognized, that the particularly geometric design of the gas activation chamber 400 shown in the figures and arrangement of the various elements of the gas activation chamber 400 shown in the figures is merely exemplary, and the concepts described herein regarding the use of a heated gas activation chamber to assist in an ALD process may be used with other designs and elements.

In the embodiment shown in FIGS. 7A, 7B, 7C and 8, heating elements 420 are provided within the gas activation chamber 400 for heating the one or more gases to a high temperature (e.g., a temperature above 550 C) sufficient to generate reaction byproducts including, for example, atomic oxygen. In the illustrated embodiment, heating coils are used to implement the heating elements 420 included within the gas activation chamber 400. Although the heating coils depicted in the figures have a uniform coil spacing, the spacing between coils and the pattern of the coils or their distance from the baffle plate may be varied in other embodiments.

FIGS. 7 and 7C illustrate one example of a baffle plate 430 design that may be provided on the underside of the gas activation chamber 400 to deliver the heated gas mixture containing the reaction byproducts to the substrate. The baffle plate 430 design shown in the figures contains a pattern of exhaust holes 440. Other baffle plate designs may also be used. For example, baffle plate 430 may instead be composed of several thin plates having complementary hole patterns. As noted above, a complementary hole patterns may be used to block direct line of sight from the heating elements 420 to the substrate. It will be recognized, however, that the baffle plate design is merely exemplary and other designs may utilize. Further, even the use of a baffle plate, may be optional.

Design simulations based on the gas activation chamber 400 shown in FIGS. 7A, 7B, 7C and 8 are effective in producing meaningful concentrations of atomic oxygen from either O₂/H₂ or O₃ at high gas temperatures (e.g., 500 C to 1200 C) and delivering the atomic oxygen to a substrate maintained at lower substrate temperatures (e.g., a temperature of 500 C or less). In one example process, an atomic oxygen dose of approximately 260 μmol/m³ may be produced per ALD cycle by injecting 3500 standard cubic centimeters per minute (sccm) of hydrogen (H₂) and 6500 sccm of oxygen (O₂) at a relatively low pressure (e.g., 2 Torr) into the gas activation chamber 400, heating the gas mixture to a high temperature (e.g., between 1000-1200 C) within the gas activation chamber 400, and delivering the heated gas mixture containing the atomic oxygen to the substrate. In this temperature range one can generate the maximum atomic oxygen and if less is needed, the O₂/H² ratio may be changed. Further, the nature of the chemistry is that a hysteresis may exists with production of atomic oxygen at lower temperatures such as 500° C. within the activation chamber. For example, if injecting H₂/O₂ with the activation chamber heater set to heat the chamber to 500° C., no intermediate combustion products such as atomic oxygen may be produced. This is because the temperature within the activation chamber is insufficient to initiate combustion. However, if the activation chamber's heating elements are first set to a sufficiently high temperature such that the chamber temperature reaches 600° C., then lowered to 500° C., it may be possible to initiate and sustain a combustion reaction. The above mentioned atomic oxygen dose may be produced while the substrate is maintained at a relatively low substrate temperature of 450 C. With a substrate temperature of 450 C, no atomic oxygen would be formed if the gas activation chamber 400 described herein were omitted, and the H₂ and O₂ gases were instead supplied directly to the substrate surface.

FIGS. 5-8 illustrate one preferred embodiment of a gas activation chamber 400 in accordance with the techniques described herein. It is recognized, however, that the gas activation chamber 400 shown in FIGS. 5-8 is merely one example of a gas activation chamber that may be used to generate reaction byproducts, such as atomic oxygen. Other gas activation chambers utilizing the techniques described herein may also be used to generate atomic oxygen.

By utilizing the gas activation chamber 400 shown and described herein, meaningful concentrations of atomic oxygen can be produced for low temperature applications without the use of plasma, which in some applications may be less favored due to problems with charge damage and poor step coverage on structures with high aspect ratios. In addition, the gas activation chamber 400 shown and described herein can be used to generate atomic oxygen using inexpensive gas sources, such as H₂ and O₂ gases. Typically, high substrate or chamber temperatures (e.g., greater than 700 C) are required to initiate the H₂/O₂ reaction that produces atomic oxygen. By utilizing gas activation chamber 400, the production of atomic oxygen is relatively independent of substrate temperature, since the high temperatures needed to initiate the reaction are generated within the gas activation chamber, as opposed to being generated at the substrate surface.

In some embodiments, the gas activation chamber 400 described herein can also be used to generate atomic oxygen using ozone (O₃), if desired, to ensure that no hydrogen containing species are present within the heated gas mixture. Ozone cannot generally be effectively used at lower temperatures (e.g., 400-800 C), due to rapid decomposition of the gas phase before reaching the substrate followed by a rapid recombination of atomic oxygen, yielding primarily oxygen (O₂) with little to no atomic oxygen (O). The rapid recombination of atomic oxygen is due to the ambient temperature being in the 400-800 C, which while sufficient to rapidly decompose ozone, is not energetic enough to slow the recombination rate of atomic oxygen. By utilizing the gas activation chamber 400 shown and described herein, ozone (O₃) can be used to produce atomic oxygen away from the substrate at higher temperatures (e.g., 900 C to 1200 C). Once produced, the heated gas mixture containing the atomic oxygen may be transported by the gas activation chamber 400 at an elevated temperature, which is sufficient to avoid recombination, before it is delivered to the substrate surface, the substrate surface being at a lower temperature.

In some cases, an atomic oxygen gradient may be present across the substrate when the gas activation chamber 400 is used. However, uniformity of the atomic oxygen generated within the gas activation chamber 400 may be improved in a number of different ways. For example, the showerhead may be divided into various zones (e.g., an inner zone, a main zone and an outer zone) and the ratio of reactive gases may be varied within each zone. In one example, the ratio of H₂/O₂ may be varied within each zone to adjust the production of atomic oxygen either higher or lower, as needed, to match a neighboring zone. In another example, a dilutant such as nitrogen (N₂) or another inert gas may be mixed with ozone (O₃) to reduce the concentration of atomic oxygen generated in one zone to match the atomic oxygen generated in a neighboring zone.

In another example, the heating elements 420 may be divided into discrete zones. In such an example, zone-to-zone temperature can be adjusted to increase or decrease the production of atomic oxygen in each zone.

In yet another example, the distance between the showerhead 120 and the gas activation chamber 400 can be varied. Adjusting the distance between the showerhead and the gas activation chamber may affect chemistry in a number of ways. For example, a shorter distance may increase the atomic oxygen concentration delivered to the substrate. Since the travel distance is reduced, the time that the atomic oxygen must travel to reach the substrate surface is reduced, which in turn, results in less atomic oxygen recombination and greater atomic oxygen concentration. As the travel distance is reduced, the temperature of the baffle plate 430 may also increase due to more direct radiative heating. This will increase the average gas temperature, which will slow the rate of atomic oxygen recombination and increase the atomic oxygen concentration delivered to the substrate. In one exemplary embodiment, the gas activation chamber may have a top to bottom dimension of 24 mm to 120 mm. Further, in exemplary embodiments, the bottom of the gas activation chamber may be located 2 mm to 40 mm above the substrate. Again, however, it will be recognized that such dimensions are merely exemplary and other dimensions may be utilized.

In yet another example, the rate of gas heating may be varied by adjusting a power input into the heating elements 420 (e.g., heating coils). However, the spacing between the heating elements 420 can also be adjusted to change the rate of gas heating. It is also possible to reduce the number of heating zones by adjusting the spacing between heating coils. Specifically, at or near the inner and outer regions of the gas activation chamber 400, the coil spacing can be reduced as the showerhead boundary is approached. This will proportionally heat the extremity of the inner and outer zones to a greater degree, thereby compensating for additional thermal losses to the vertical walls of the gas activation chamber 400.

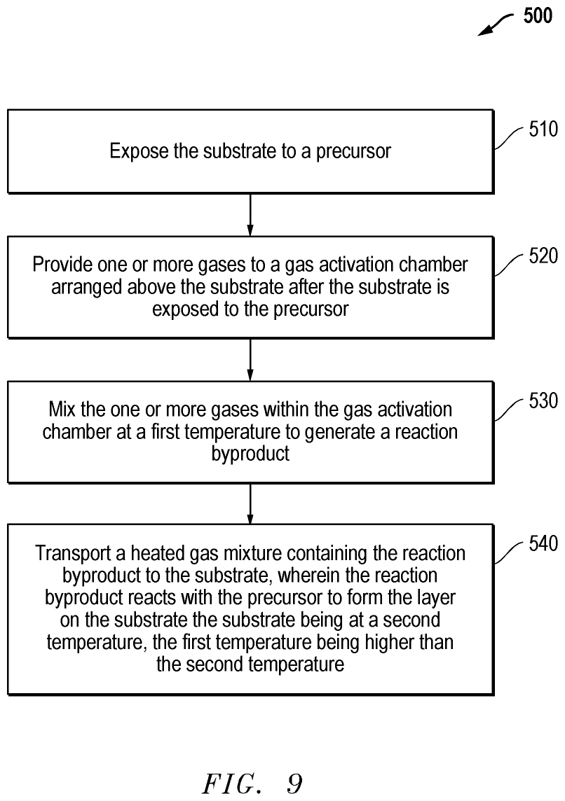

FIG. 9 illustrates one embodiment of an exemplary method that uses the techniques described herein. It will be recognized that the embodiment shown in FIG. 9 is merely exemplary and additional methods may utilize the techniques described herein. Further, additional processing steps may be added to the method shown in FIG. 9 as the steps described are not intended to be exclusive. Moreover, the order of the steps is not limited to the order shown in the figures as different orders may occur and/or various steps may be performed in combination or at the same time.

FIG. 9 illustrates one embodiment method 500 for performing atomic layer deposition of a layer on a substrate. As shown in FIG. 9, the method 500 may include exposing the substrate to a precursor in step 510. After the substrate is exposed to the precursor, one or more gases may be provided to a gas activation chamber arranged above the substrate in step 520. In step 530, the one or more gases may be mixed within the gas activation chamber at a first temperature to generate a reaction byproduct. In step 540, a heated gas mixture containing the reaction byproduct may be transported to the substrate, wherein the reaction byproduct reacts with the precursor to form the layer on the substrate, the substrate being at a second temperature, the first temperature higher than the second temperature.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A system for atomic layer deposition (ALD) processing of a substrate, the system comprising:
a gas source configured to provide one or more gases;
a gas activation chamber arranged between the gas source and the substrate;
a heat source;
wherein the gas activation chamber is coupled to receive the one or more gases provided from the gas source, wherein the gas activation chamber is configured so that the one or more gases are mixed within the gas activation chamber and heated at a first temperature to produce a reaction byproduct which includes atomic oxygen; and
wherein the system is configured to allow the substrate to be maintained at a second temperature, the second temperature being lower than the first temperature.

2. The system of claim 1, wherein the gas activation chamber is configured to transport a heated gas mixture containing the reaction byproduct to the substrate at an elevated temperature.

3. The system of claim 1, wherein the first temperature is between 500 C and 1200 C and the second temperature is lower than 500 C.

4. The system of claim 1, wherein the gas source comprises a showerhead, the showerhead is configured to inject the one or more gases into the gas activation chamber.

5. The system of claim 4, wherein the gas activation chamber includes a plurality of injector holes and a gas activation chamber injection hole pattern matches a showerhead injector hole pattern.

6. The system of claim 1, wherein the gas activation chamber is formed from a material having low thermal conductivity.

7. The system of claim 1, wherein the gas activation chamber is formed from quartz.

8. The system of claim 1, wherein the gas activation chamber includes the heat source, one or more heating elements of the heat source heating the one or more gases within the gas activation chamber, and the gas activation chamber maintaining the heated gas mixture containing the reaction byproduct at the elevated temperature while transporting the heated gas mixture containing the reaction byproduct to the substrate.

9. The system of claim 8, wherein a baffle plate containing a plurality of exhaust holes is provided on an underside of the gas activation chamber to deliver the heated gas mixture containing the reaction byproduct to the substrate.

10. The system of claim 9, wherein the baffle plate comprises a plurality of thin plates having complementary hole patterns, which block direct line of sight from the one or more heating elements to the substrate.

11. The system of claim 1, wherein the system is a spatial atomic layer deposition (ALD) system having a rotating platen.

12. The system of claim 11, wherein the system is configured to perform a low pressure radical oxidation (LPRO) process by exposing the substrate to a precursor before the substrate is exposed to atomic oxygen, and wherein the atomic oxygen is generated within the gas activation chamber and transported to the substrate, where it reacts with the precursor to deposit a layer on the substrate.

13. The system of claim 11, wherein the first temperature is above 550 C and the second temperature is below 500 C.

14. A method for performing atomic layer deposition of a layer on a substrate, the method comprising:
exposing the substrate to a precursor;
providing one or more gases to a gas activation chamber arranged above the substrate after the substrate is exposed to the precursor;
mixing the one or more gases within the gas activation chamber at a first temperature to generate a reaction byproduct; and
transporting a heated gas mixture containing the reaction byproduct to the substrate, wherein the reaction byproduct reacts with the precursor to form the layer on the substrate, the substrate being at a second temperature, the first temperature higher than the second temperature.

15. The method of claim 14, wherein the reaction byproduct generated within the gas activation chamber comprises atomic oxygen and the layer deposited on the substrate comprises an oxide.

16. The method of claim 15, wherein the precursor contains a metal and the layer deposited on the substrate is a metal oxide.

17. The method of claim 15, wherein the one or more gases comprise oxygen (O₂) and hydrogen (H₂).

18. The method of claim 15, wherein the one or more gases include ozone (O₃).

19. The method of claim 15, wherein the first temperature is above 550 C and the second temperature is below 500 C.

20. The method of claim 19, the method is a spatial atomic layer deposition (ALD) process using a rotating platen, wherein the method further comprises cyclically exposing the substrate to the precursor and the reaction byproduct.
